(19) United States
(12) Patent Application Publication
(10) Pub. No.: US 2008/0122070 A1
(43) Pub. Date: May 29, 2008

(54) Heat dissipating semiconductor package and fabrication method therefor

(75) Inventors: Wen-Tsung Tseng, Taichung (TW); Ho-Yi Tsai, Taichung Hsien (TW); Chien-Ping Huang, Hsinchu Hsein (TW); Chih-Wei Chang, Taichung (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 11/986,359

(22) Filed: Nov. 21, 2007

(30) Foreign Application Priority Data
Nov. 24, 2006 (TW) 095143488

(51) Int. Cl. H01L 23/373; H01L 21/58

(52) U.S. Cl. 257/720; 438/122; 257/E23.101; 257/E21.505

(57) ABSTRACT

A heat dissipating semiconductor package and a fabrication method therefor are provided. The fabrication method for the heat dissipating semiconductor package mainly includes steps of: containing a substrate having a chip mounted thereon in an aperture of a carrier; mounting a heat dissipating sheet having supporting portions on the carrier with the heat dissipating sheet being attached on the chip; forming an encapsulant to encapsulate the semiconductor chip and the heat dissipating structure; removing a part of the encapsulant above the heat dissipating sheet with a part of the heat dissipating sheet exposed from the encapsulant by lapping; and forming a cover layer on the part of heat dissipating sheet to prevent it from oxidation; and cutting along a predetermined size of the semiconductor package, thereby heat generated from an operation of the chip is dissipated via the heat dissipating structure.

### BACKGROUND OF THE INVENTION

1. Field of the Invention

The present invention generally relates to a semiconductor package and a fabrication method therefor, and more particularly, to a heat dissipating semiconductor package, with which a heat dissipating structure is integrated, and the fabrication method therefor.

2. Description of Related Art

Along with the demand for lighter and smaller electronic product, it is the main stream to produce ball grid array (BGA) semiconductor package with sufficient amounts of input/output connections for the chips with dense electronic components and electronic circuits. However, a lot of heat is generated in the semiconductor package with dense electronic components and electronic circuits. If heat cannot be dissipated immediately from the surface of the chip, the electricity function and product stability of the semiconductor chip will be affected thereby. In addition, the semiconductor chip encapsulated with an encapsulant being made of an encapsulation resin that is poor in thermal conductivity, where the thermal conductivity coefficient of the encapsulation resin is around 0.8 w/m° K, the heat generated from the chip active surface with a plurality of circuits thereon is unable to be effectively and quickly dissipated through the encapsulant, thus the chip functions and durability are affected.

In view of the above heat dissipating problems in the conventional ball grid array semiconductor package, U.S. Pat. Nos. 6,458,626, and 6,444,498 disclosing a BGA semiconductor package having a heat dissipating structure attached thereto is illustrated in FIGS. 1A-1C. The semiconductor package has a substrate 13, a semiconductor chip 10 mounted on the substrate 13, a heat dissipating sheet 11 directly attached on the semiconductor chip 10, an interface layer 15 formed on a surface of a heat dissipating sheet 11, and an encapsulant 14 completely encapsulate the heat dissipating sheet 11 and the semiconductor chip 10, wherein the heat dissipating sheet 11 is extended outwardly to maximize the exposed surface thereof and prevent the resin flush from the occurrence. The interface layer 15 provided has a poor bonding with the encapsulant 14 for exposing the surface of the heat dissipating sheet 11 from the encapsulant 14 after a further cutting process.

As shown in FIG. 1B, if a bonding between the interface layer 15 (e.g., a plated gold layer) and the heat dissipating sheet 11 is stronger than that between the interface layer 15 and the encapsulant 14, the interface layer 15 is kept on the heat dissipating sheet 11 after the encapsulant 14 has been removed after the further cutting process.

Alternatively, as shown in FIG. 1C, if a bonding between the interface layer 15 (e.g., an adhesive tape made up of polymeric resin) and the heat dissipating sheet 11 is weaker than that between the interface layer 15 and the encapsulant 14, the interface layer 15 will be removed from the heat dissipating sheet 11 with the encapsulant 14.

However, as the heat dissipating sheet 11 is extended outwardly, the cutting tool goes directly through the heat dissipating sheet, which is usually made of metal such as copper or aluminum, and easily causes metal burrs of the heat dissipating sheet, thereby affecting an appearance of the package, increasing a consumption of the cutting knife, and causing higher production cost and lower production efficiency.

In addition, Taiwan Patent No. 1255047 discloses a heat dissipating semiconductor package with the following steps illustrated in FIGS. 2A to 2C. A substrate 23 having a semiconductor chip 20 mounted thereon is positioned into a predetermined aperture 220 of a carrier 22, wherein, a planar size of the substrate 23 is close to a predetermined planar size of the semiconductor package. A heat dissipating structure 21 comprising a heat dissipating sheet 211 and a supporting portion 212 is mounted on a carrier 22 for positioning the semiconductor chip 20 beneath the heat dissipating sheet 211. An encapsulant 24 is formed on the substrate 23 and the carrier 22 to encapsulate the semiconductor chip 20 and the heat dissipating structure 21 by a molding process, wherein, a planar size covered by the encapsulant 24 is greater than that defined by the supporting portion 212 of the heat dissipating structure 21. A cutting process is performed to cut along outlines of a predetermined size of the semiconductor package, and thereby portions going beyond the predetermined planar size of the semiconductor package, such as a portion of the encapsulant 24 and the supporting portion 212 are removed.

Furthermore, as shown in FIGS. 3A and 3B, which are diagrams of a heat dissipating semiconductor package according to U.S. Pat. No. 5,886,408, wherein a heat dissipating structure 31 is directly mounted on a semiconductor chip 30; a molding process is performed to form an encapsulant 34 that encapsulates the heat dissipating structure 31 and the semiconductor chip 30; and then a surface of the heat dissipating structure 31 is exposed by lapping a part of the encapsulant 34.

However, due to the heat dissipating structure 31 exposed from the encapsulant 34 after lapping are mainly made of copper in the aforementioned heat dissipating semiconductor packages, the heat dissipating structure 31 are oxidize and form a cupric oxide after being exposed to the air for a long time, thereby affecting not only an appearance of the package but also a heat dissipating efficiency of the heat dissipating sheet.

Therefore, there is an urgent need providing a semiconductor package and fabrication method therefor that can overcome the above-mentioned drawbacks.

### SUMMARY OF THE INVENTION

In view of the disadvantages of the prior art mentioned above, it is a primary objective of the present invention to provide a heat dissipating semiconductor package and a fabrication method therefor, which is capable of preventing a part of heat dissipating structure exposed from an encapsulant from being oxidized, and further preventing an undesirable appearance and a reduced heat dissipating efficiency due to oxidation.

It is another objective of the present invention to provide a heat dissipating semiconductor package and a fabrication method therefor, which is capable of reducing worn out of a cutting tool in the fabrication process.

It is a further objective of the present invention to provide a heat dissipating semiconductor package and a fabrication method therefor for allowing a direct contact of the heat dissipating structure with the semiconductor chip, thus obtaining an excellent heat dissipating efficiency.

To achieve the aforementioned and other objectives, a fabrication method for a heat dissipating semiconductor package is provided according to the present invention. The fabrication method of heat dissipating semiconductor package of the present invention comprises: providing a substrate having a semiconductor chip mount thereon, and a carrier with an aperture for containing the substrate therein, wherein a size of the substrate is close to a predetermined size of the semiconductor package; providing a heat dissipating structure comprising a heat dissipating sheet and a plurality of supporting portions extending downwardly from edges of the heat dissipating sheet, thus to have the supporting portions of the heat dissipating structure being mounted on the carrier; forming an encapsulant on the substrate and the carrier to encapsulate the semiconductor chip and the heat dissipating structure; removing a part of the encapsulant above the heat dissipating sheet of the heat dissipating structure by lapping for exposing a part of the heat dissipating sheet from the encapsulant; forming a cover layer on a surface of the part heat dissipating sheet exposed from the encapsulant; and cutting along the predetermined planar size of the semiconductor package, thus the semiconductor package is produced. The cover layer is formed by screen printing materials, such as epoxy, on the surface of part of the heat dissipating sheet exposed from the encapsulant.

The heat dissipating sheet has a protruding portion on a center thereof, and a top surface of the protruding portion is exposed from the encapsulant. The top surface of the protruding portion has a cover layer of ink for example for preventing it from oxidization, meanwhile, a remaining part of the heat dissipating sheet is still encapsulated by the encapsulant in order to increase a bonding between the heat dissipating structure and the encapsulant. The heat dissipating sheet further has an extension portion at each of four corners thereof for allowing a cutting tool to cut through the extension portions only rather than the entire heat dissipating sheet in the later cutting process according to the predetermined planar size of the semiconductor package, wherein the extension portion is connected with the supporting portion, thereby reducing worn out of the cutting tool. A surface, which is opposing to the surface of the part of the heat dissipating sheet exposed from the encapsulant, of the heat dissipating sheet of the heat dissipating structure is contacted with the semiconductor chip via a heat conductive gel mounted therebetween, thus heat generated during operating of the semiconductor chip is dissipated via the heat dissipating structure.

The present invention further discloses a heat dissipating semiconductor package that comprises: a substrate; a semiconductor chip mounted on and electrically connected to the substrate; a heat dissipating sheet mounted on the semiconductor chip via a heat conductive gel; an encapsulant formed on the substrate to encapsulate the semiconductor chip with a top surface of the heat dissipating sheet exposed therefrom; a cover layer completely covering a top surface of the encapsulant and the top surface of the heat dissipating sheet exposed from the encapsulant. The heat dissipating sheet has a protruding portion on a center thereof, and a top surface of the protruding portion is exposed from the encapsulant and is covered by a cover layer in order to prevent the top surface of the protruding portion from oxidization. The heat dissipating sheet further has an extension portion at each of four corners thereof, where side surfaces of the extension portions are flush with those of the encapsulant.

In view of the foregoing descriptions, the heat dissipating semiconductor package and a fabrication method therefor according to the present invention mainly has the following steps: positioning a substrate having a chip mounted thereon into an aperture of a carrier; attaching a heat dissipating structure having a heat dissipating sheet and supporting portions onto the substrate; after encapsulation, removing a part of the encapsulant to expose a part of the heat dissipating sheet from the encapsulant by lapping; and forming a cover layer such as an ink on the part of the heat dissipating sheet exposed from the encapsulant by such as a screen printing and the like, thereby preventing the part of heat dissipating sheet exposed from the encapsulant from oxidizing

Furthermore, the heat dissipating sheet of the heat dissipating structure of the present invention has a protruding portion on a center area thereof, where a top surface of the protruding portion is exposed from the encapsulant with a remaining part of the heat dissipating sheet remaining encapsulated inside the encapsulant for increasing a bonding between the heat dissipating structure and the encapsulant. The heat dissipating sheet further has an extension portion at each of four corners thereof for allowing a cutting tool cutting through the extension portions only rather than the entire heat dissipating sheet in the subsequent cutting process according to the predetermined planar size, thereby reducing worn out of the cutting tool. A surface, which is opposing to a top surface of the part of the heat dissipating sheet exposed from the encapsulant, of the heat dissipating sheet of the heat dissipating structure is contacted with the semiconductor chip via a heat conductive gel, thus heat generated during semiconductor chip operation is more quickly dissipated by the heat dissipating structure.

### BRIEF DESCRIPTION OF DRAWINGS

The present invention can be more fully understood by reading the following detailed description of the preferred embodiments, with reference made to the accompanying drawings, wherein:

FIGS. 1A to 1C (PRIOR ART) are diagrams showing a heat dissipating semiconductor package according to U.S. Pat. Nos. 6,458,626, and 6,444,498;

FIGS. 2A to 2C (PRIOR ART) are diagrams showing a heat dissipating semiconductor package according to Taiwan Patent No. I255047;

FIGS. 3A and 3B (PRIOR ART) are diagrams of heat dissipating semiconductor package according to U.S. Pat. No. 5,886,408;

FIGS. 4A to 4F are schematic diagrams of a fabrication method for a heat dissipating semiconductor package according to a first embodiment of the present invention; and

FIG. 5 is a schematically cross-sectional of a heat dissipating semiconductor package according to a second embodiment of the present invention.

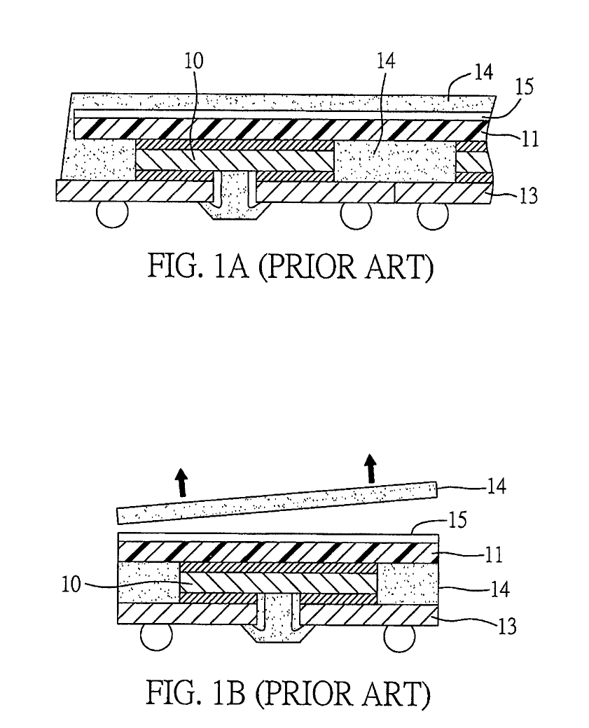

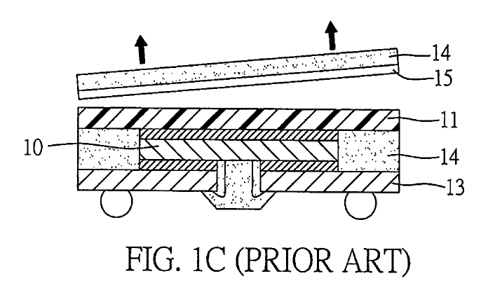

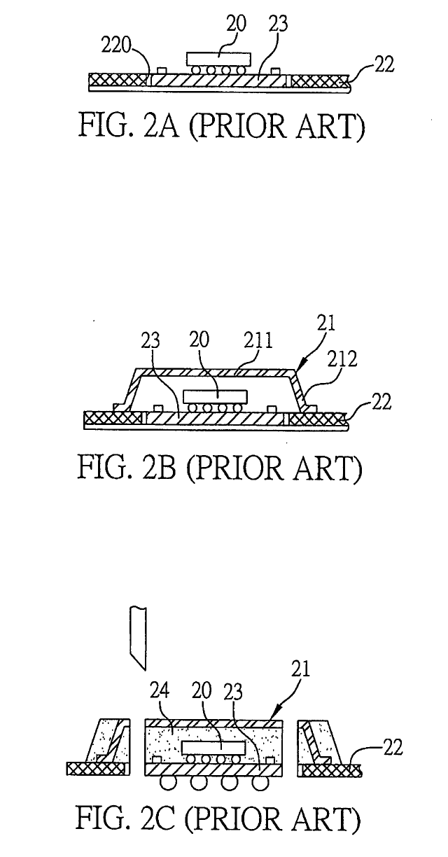

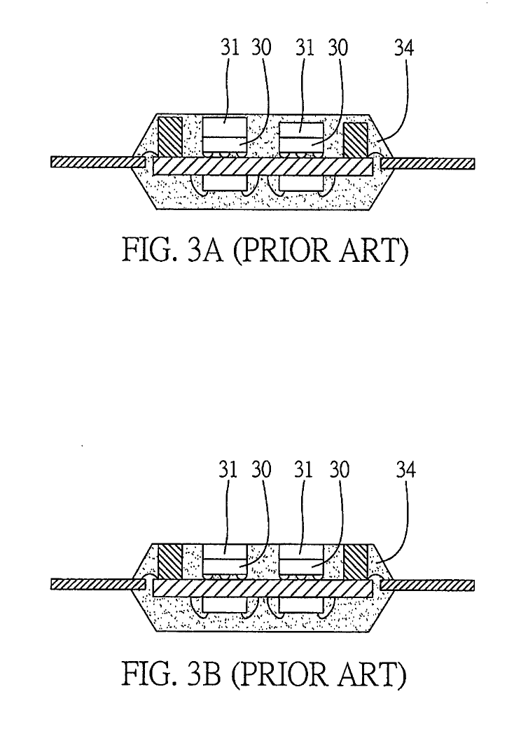

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

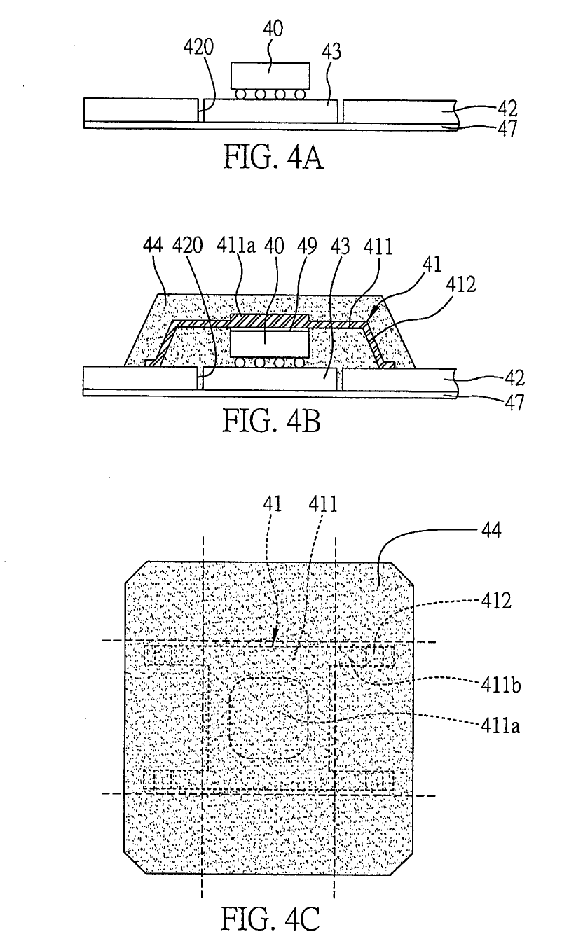

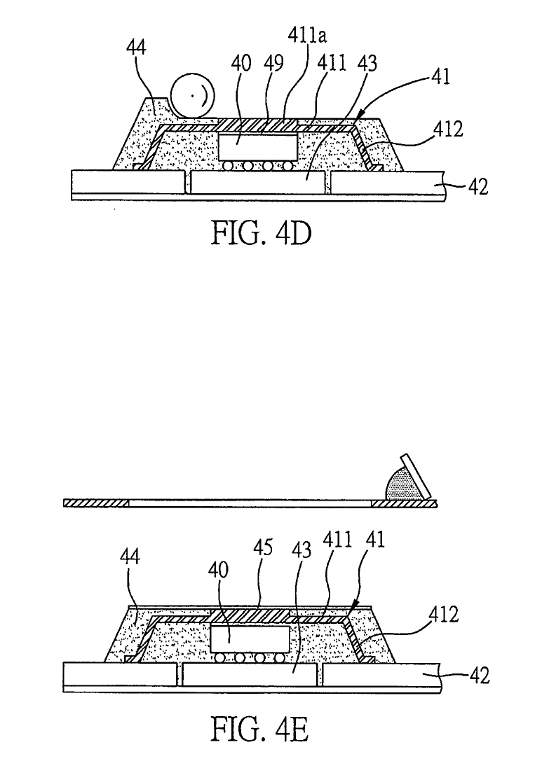

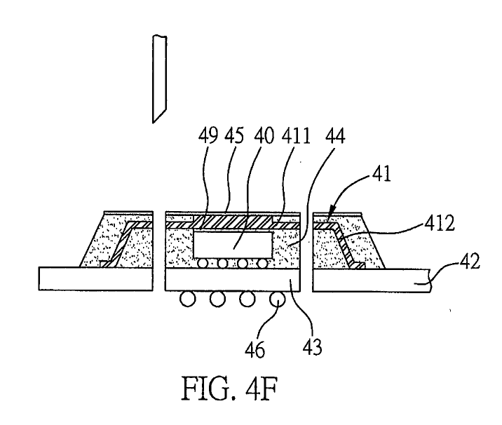

Please refer to FIGS. 4A to 4F, which are diagrams of a fabrication method for a heat dissipating semiconductor package according to a first embodiment of the present invention.

As shown in FIG. 4A, a substrate 43 and a carrier 42 are provided, where a planar size of the substrate 43 is close to a predetermined planar size of a semiconductor package to be formed. At least one semiconductor chip 40 is mounted on and electrically connected to the substrate 43. The semiconductor chip 40 can be electrically connected to the substrate 43 by means of flip chip technique as shown in FIG. 4A or by wire bonding (not shown).

The carrier 42 has an aperture 420, and a planar size of the aperture 420 is larger than that of the substrate 43 for allowing the substrate 43 with the semiconductor chip 40 mounted thereon being disposed in the aperture 420, meanwhile, a tape 47 could be applied on bottom surfaces of the substrate 43 and the carrier 42 to cover gaps between the substrate 43 and the aperture 420 for positioning the substrate 43 and sealing the gap at the same time.

The tape 47 could be made of a high temperature resistant polymer, and the carrier 42 can be made of an organic insulating material, such as FR4, FR5, BT, and etc. The aperture 420 of the carrier 42 can be one or more for containing therein one or more substrate having a chip mounted thereon. Alternatively, the gaps between the substrates 43 and the carrier 42 could be covered or sealed by a plurality of small size tapes, thereby reducing the amount of tape needed. Alternatively, the gaps between the substrates 43 and the carrier 42 could be filled with a gel made of polymer, e.g., solder resist or epoxy (not shown) in order to position the substrate 43 and to seal the gaps.

Please refer to FIGS. 4B and 4C, wherein, FIG. 4C is a top view diagram corresponding to FIG. 4B. A heat dissipating structure 41 made of a material,. e.g., copper, is provided, where the heat dissipating structure 41 includes a heat dissipating sheet 411 and a supporting portions 412 extended downwardly from edges of the heat dissipating sheet 411. The supporting portions 412 of the heat dissipating structure 41 is mounted on and electrically connected to the carrier 42. The heat dissipating sheet 411 is attached on the semiconductor chip 40 by a heat conductive gel 49. Therefore, heat generated during an operation of the semiconductor chip can be directly dissipated via the heat dissipating structure 41.

The heat dissipating sheet 411 of the heat dissipating structure 41 has a protruding portion 411a on a center area thereof, and an extension portion 411b extended at each of four corners thereof, where the extension portions 411b are connected with the supporting portions 412. As shown in FIG. 4C, only the extension portions 411b of the heat dissipating structure 41 are at predetermined cutting paths (shown as the dashed lines) of the semiconductor package, for allowing a cutting tool cutting through only the extension portions 411b rather than the entire heat dissipating sheet 411 in the later cutting process according to the predetermined size of the semiconductor package, thereby reducing worn out of the cutting tool.

Next, an encapsulant 44 is formed on the carrier 42 and the substrate 43 to encapsulate the semiconductor chip 40 and the heat dissipating structure 41. A planar size covered by the encapsulant 44 is larger than a planar size surrounded by the supporting portions 412 of the heat dissipating structure 41, and a thickness of the encapsulant 44 is larger than a height of the heat dissipating structure 41, thus the encapsulant 44 can cover the heat dissipating structure 41 completely. Meanwhile, the encapsulant 44 is capable of filling up into the gaps between the substrates 43 and the apertures 420 of the carrier 42.

As shown in FIG. 4D, a part of the encapsulant 44 above the heat dissipating sheet 411 of the heat dissipating structure 41 is removed to expose a part of the heat dissipating sheet 411 from the encapsulant 44 by means of, e.g., lapping or the like. In other words, a top surface of the protruding portion 411a that is on a top center of the heat dissipating sheet 411 is exposed from the encapsulant 44, meanwhile, a remaining part of the heat dissipating sheet 411 is remained encapsulated inside the encapsulant 44 in order to increase a bonding between the heat dissipating structure 41 and the encapsulant 44.

As shown in FIG. 4E, forming a cover layer 45 on a top surface of the encapsulant 44 and a top surface of the heat dissipating sheet 411 exposed from the encapsulant 44 with a quick coated ink, e.g., epoxy, by means of screen printing or the like for protecting the top surface of the heat dissipating sheet 411 exposed from the encapsulant 44.

As shown in FIG. 4F, the tape 47 is removed, and then a plurality of solder balls 46 are mounted on a surface of the substrate 43 that has no semiconductor chip mounted thereon. Cutting the semiconductor package along outlines of the predetermined size, namely, about the planar size of the substrate 43, thus the semiconductor package of the present invention is completely produced.

By means of the aforementioned fabrication method, a semiconductor package according to an embodiment of the present invention is disclosed, which comprises: the substrate 43; the semiconductor chip 40 mounted on and electrically connected to the substrate 43; the heat dissipating sheet 411 attached onto the semiconductor chip 40 via a heat conductive gel 49; an encapsulant 44 formed on the substrate 43 to encapsulate the semiconductor chip 40 with a top surface of the heat dissipating sheet 411 exposed therefrom; and a cover layer 45 formed on a top surface of the encapsulant 44 and the top surface of the heat dissipating sheet 411.

The heat dissipating sheet 411 has a protruding portion 411a on a top center thereof, a top surface of the protruding portion 411a is exposed from the encapsulant 44. In addition, A cover layer 45 covers an entire top surface of the semiconductor package, which includes a top surface of the encapsulant 44 and the top surface of the heat dissipating sheet 411 exposed from the encapsulant 44. Furthermore, the heat dissipating sheet 411 comprises an extension portion 411a at each of four corners thereof. Since the extension portions 411a are on predetermined cutting paths of the semiconductor package, side surfaces of the extension portions 411b are flushed with that of the encapsulant 44.

### Second Embodiment

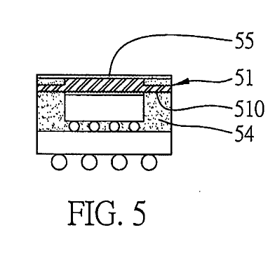

Please refer to FIG. 5, which is a diagram of a heat dissipating semiconductor package according to a second embodiment of the present invention.

As shown in FIG. 5, the heat dissipating semiconductor package of the present embodiment is similar to the foregoing embodiment, and the present embodiment is different from the foregoing embodiment in that a heat dissipating structure 51 of the present embodiment is further processed with a roughening treatment that can be made by a acidity or alkaline chemical to form a rough surface 510, where the rough surface 510 provides a better bonding between the heat dissipating structure 51 and an encapsulant 54, and is also good for a later coating process for forming a cover layer 55 that covers a part of the heat dissipating structure 51 exposed from the encapsulant 54 after a process of removing a part of the encapsulant 54 above the heat dissipating structure 51.

In view of the foregoing descriptions, a heat dissipating semiconductor package and a fabrication method therefor according to the present invention mainly has the following steps: containing a substrate having a chip mounted thereon in an aperture of a carrier; attaching a heat dissipating structure having a heat dissipating sheet and supporting portions on the carrier; after an encapsulation process, removing a part of the encapsulant to expose a part of the heat dissipating sheet from the encapsulant by lapping; and forming a cover layer such as an ink on the part of the heat dissipating sheet exposed from the encapsulant by means of, e.g., screen printing or the like, thereby preventing the part of heat dissipating sheet from oxidizing.

Furthermore, the heat dissipating sheet of the heat dissipating structure of the present invention has a protruding portion on a top center area thereof, where a top surface of the protruding portion is exposed from the encapsulant, meanwhile, a remaining part of the heat dissipating sheet is still encapsulated inside the encapsulant to increase a bonding between the heat dissipating structure and the encapsulant. The heat dissipating sheet further has an extension portion at each of four corners thereof with a cutting tool cutting on the extension portions only rather than the entire heat dissipating sheet in a later cutting process according to the predetermined planar size of the package, thereby reducing worn out of the cutting tool. A surface of the heat dissipating sheet of the heat dissipating structure, which is opposing to the top surface that is exposed from the encapsulant, can be mounted on the semiconductor chip by a heat conductive gel, thus heat generated during operation of semiconductor chip can be dissipated via the heat dissipating structure.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A fabrication method for a heat dissipating semiconductor package, comprising steps of:
providing a substrate having a chip mounted thereon and a carrier having an aperture for containing the substrate therein, wherein a size of the substrate is close to a predetermined size of the semiconductor package;
providing a heat dissipating structure having a heat dissipating sheet and a plurality of supporting portions extended downwardly from edges of the heat dissipating sheet;
mounting the supporting portions of the heat dissipating structure on the carrier;
forming an encapsulant on the substrate and the carrier to encapsulate the semiconductor chip and the heat dissipating structure;
removing a part of the encapsulant above the heat dissipating sheet of the heat dissipating structure for exposing a part of the heat dissipating sheet from the encapsulant;
forming a cover layer on the part of the heat dissipating sheet exposed from the encapsulant; and
cutting along edges of the predetermined size of the semiconductor package.

2. The fabrication method of claim 1, wherein, the cover layer covers a top surface of the encapsulant and the part of the heat dissipating sheet exposed from the encapsulant.

3. The fabrication method of claim 1, wherein, the substrate is made of an organic insulating material being one selected from a group consisting of FR4, FR5, BT, and a combination thereof.

4. The fabrication method of claim 1, wherein the heat dissipating sheet of the heat dissipating structure is attached to a top of the semiconductor chip via a heat conductive gel.

5. The fabrication method of claim 1, wherein, the heat dissipating sheet of the heat dissipating structure has a protruding portion on a center area thereof, a top surface of the protruding portion is exposed from the encapsulant for servicing as the part of the heat dissipating sheet exposed from the encapsulant, and the heat dissipating sheet has an extension portion at each of four corners thereof with only the extension portions of the heat dissipating structure positioned at predetermined cutting paths of the semiconductor package, where the extension portions are connected with the supporting sections.

6. The fabrication method of claim 5, wherein, the part of the encapsulant above the heat dissipating sheet of the heat dissipating structure is removed by lapping for exposing the top surface of the protruding portion of the heat dissipating sheet from the encapsulant and keeping a remaining part of the heat dissipating sheet be encapsulated inside the encapsulant.

7. The fabrication method of claim 5, wherein, side surfaces of the extension portions are flush with that of the encapsulant.

8. The fabrication method of claim 1, wherein, the cover layer is made of epoxy.

9. The fabrication method of claim 1, further comprising a roughening treatment on a surface of the heat dissipating structure to form a rough surface thereof, thus providing a better bonding between the heat dissipating structure and the encapsulant.

10. A heat dissipating semiconductor package, comprising:
a substrate;
a semiconductor chip mounted on and electrically connected to the substrate;
a heat dissipating sheet mounted on the semiconductor chip via a heat conductive gel;
an encapsulant formed on the substrate to encapsulate the semiconductor chip with a top surface of the heat dissipating sheet exposed therefrom; and
a cover layer covering the top surface of the heat dissipating sheet exposed from the encapsulant.

11. The heat dissipating semiconductor package of claim 10, wherein the heat dissipating sheet has a protruding portion on a center area thereof for allowing the top surface of the heat dissipating sheet being exposed from the encapsulant with a remaining part of the heat dissipating sheet being encapsulated inside the encapsulant.

12. The heat dissipating semiconductor package of claim 10, wherein the heat dissipating sheet further has an extension portion at each of four corners thereof, and side surfaces of the extension portions are flush with that of the encapsulant.

13. The heat dissipating semiconductor package of claim 10, wherein the encapsulant is made of epoxy.

14. The heat dissipating semiconductor package of claim 10, wherein the heat dissipating sheet has a rough surface.

15. The heat dissipating semiconductor package of claim 14, wherein the rough surface is formed by a roughing treatment.

16. The heat dissipating semiconductor package of claim 10, wherein the cover layer further covers a top surface of the encapsulant.
